(19) United States
(12) Patent Application Publication
(10) Pub. No.: US 2022/0396042 A1
(43) Pub. Date: Dec. 15, 2022

(54) MOLDING APPARATUS, MOLDING METHOD, AND PRODUCT MANUFACTURING METHOD

(71) Applicant: CANON KABUSHIKI KAISHA, Tokyo (JP)

(72) Inventor: Shunsuke Ota, Tochigi (JP)

(21) Appl. No.: 17/839,144

(22) Filed: Jun. 13, 2022

(30) Foreign Application Priority Data
Jun. 15, 2021 (JP) 2021-099402

(51) Int. Cl. B29C 71/04; B29C 59/02; B29C 59/00; B29C 33/22

(52) U.S. Cl. CPC B29C 71/04; B29C 59/022; B29C 59/002; B29C 33/22

(57) ABSTRACT

Curing processing for curing a curable composite is performed in a state where a mold held by a mold holding unit and a substrate held by a substrate holding unit are in contact with each other through a curable composite, and mold release processing of the mold from the substrate is performed after the curing processing. In a case where the mold release processing fails, additional curing processing is performed. This enables releasing the mold even without performing recovery processing by an operator, thereby making it possible to provide a molding apparatus that is beneficial in productivity.

### BACKGROUND

### Field of the Disclosure

The present disclosure relates to a molding apparatus, a molding method, and a product manufacturing method.

### Description of the Related Art

With the increased demand for miniaturization of semiconductor devices and micro electro mechanical systems (MEMS), there has been noticed an imprint technique that enables minute pattern (structure) forming in the order of several nanometers on a substrate as well as the conventional photo-lithography technique. The imprint technique is a microfabrication technique for supplying (applying) an uncured imprint material (curable composite) onto a substrate and bringing the imprint material and a mold into contact with each other. Thus, a pattern corresponding to a minute concave-convex pattern formed on the mold is formed on the substrate. More specifically, by curing the imprint material in a state where the mold is in contact with the imprint material supplied to a shot region on the substrate and then detaching the mold from the cured imprint material, the pattern of the imprint material can be formed on the substrate.

When detaching (releasing) the mold from the cured imprint material on the substrate, a large stress is momentarily applied to an interface between the mold and the imprint material (a surface where the mold and the imprint material are in contact with each other). Such a stress is known to cause a distortion in the pattern of the imprint material formed on the substrate, leading to an issue that a pattern defect arises. In addition, the stress is also known to cause a phenomenon in which the mold and the substrate cannot be held by respective holding units (chucks) (this phenomenon is a dechuck), since the mold cannot be normally detached from the cured imprint material.

To avoid the occurrence of such a dechuck, it is considered to predict the occurrence of a dechuck based on image information by a sensor or camera in an apparatus and then perform processing for increasing a mold holding force of the mold chuck and a substrate holding force of the substrate chuck (Japanese Patent Application Laid-Open No. 2018-6379).

However, even if the mold holding force and the substrate holding force are increased as discussed in Japanese Patent Application Laid-Open No. 2018-6379, the mold may not possibly be released if a mold release force exceeding these holding forces is required. In such a case, an operator needs to perform recovery processing so that a lot of time is required until a normal condition is restored, thereby resulting in reduced productivity of an imprint apparatus.

### SUMMARY

The present disclosure is directed to providing a molding apparatus that is beneficial in productivity even if a mold cannot be released from a substrate.

According to an aspect of the present disclosure, a molding apparatus includes a mold holding unit configured to hold a mold, a substrate holding unit configured to hold a substrate, a driving unit configured to adjust a relative distance between the mold held by the mold holding unit and the substrate held by the substrate holding unit, and a control unit configured to control the driving unit to perform curing processing for curing a curable composite in a state where the mold held by the mold holding unit and the substrate held by the substrate holding unit are in contact with each other through the curable composite, and to perform mold release processing of the mold from the substrate after the curing processing, wherein, when the mold release processing fails, the control unit performs control to performing additional processing on the curable composite between the mold held by the mold holding unit and the substrate held by the substrate holding unit.

Further features of the present invention will become apparent from the following description of exemplary embodiments with reference to the attached drawings.

### BRIEF DESCRIPTION OF THE DRAWINGS

FIG. 1 is a schematic view illustrating a configuration of an imprint apparatus as an example of a molding apparatus of the present disclosure.

FIG. 2 is a flowchart illustrating recovery processing according to a first exemplary embodiment.

FIG. 3 is a flowchart illustrating recovery processing according to a second exemplary embodiment.

FIGS. 4A, 4B, 4C, 4D, 4E, and 4F illustrate a product manufacturing method.

### DESCRIPTION OF THE EMBODIMENTS

Exemplary embodiments of the present disclosure will be described below with reference to the accompanying drawings. In each drawing, identical members are assigned the same reference numeral, and redundant descriptions thereof will be omitted.

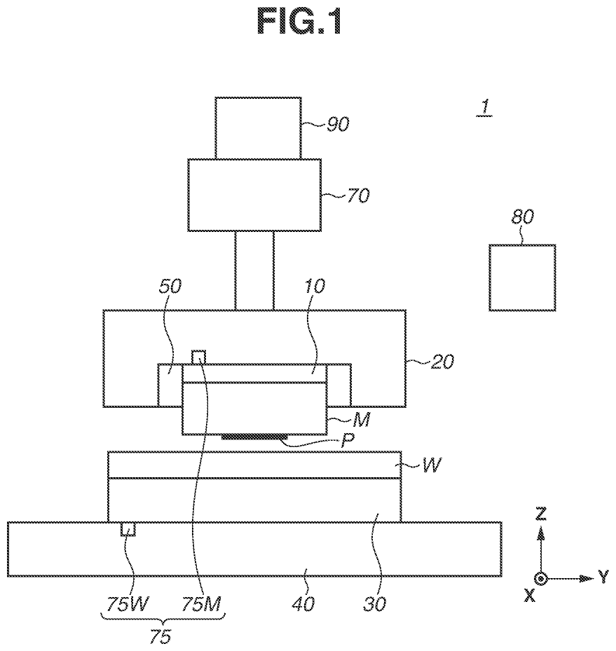

FIG. 1 is a schematic view illustrating a configuration of an imprint apparatus 1 as an example of a molding apparatus according to the present disclosure. The imprint apparatus 1 is a lithography apparatus that forms a concave-convex pattern of an imprint material on a substrate using a mold having a minute concave-convex pattern. The imprint apparatus 1 brings the imprint material supplied on the substrate into contact with the mold and applies curing energy to the imprint material to form a pattern of a cured object with the mold concave-convex pattern transferred thereon.

A curable composite (sometimes refer to as a resin in the uncured state) that is cured when the curing energy is applied is used as the imprint material. An electromagnetic wave and heat are used as the curing energy. For example, infrared rays, visible rays, ultraviolet rays, and other rays of which the wavelength is selected from a range from 10 nm to 1 mm inclusive are used as the electromagnetic wave.

The curable composite is a composite that is cured by light irradiation or heating. A photo-curable resin that is cured by light irradiation contains at least a polymerizable compound and a photopolymerization initiator and may contain a non-polymerizable compound or a solvent as required. The non-polymerizable compound is of at least one type selected from such groups as sensitizers, hydrogen donors, internal mold release agents, interfacial active agents, antioxidants, and polymer components. An imprint apparatus that adopts the photo-curing method based on ultraviolet irradiation will be descried below.

The imprint material can be applied onto the substrate in the form of a film by a spin coater or slit coater. Alternatively, the imprint material can be applied onto the substrate in the form of droplets, in the form of an island formed of a series of a plurality of droplets, or in the form of a film by a liquid discharge head. The viscosity (at 25° C.) of the imprint material is, for example, 1 mPa-s or above and 100 mPa-s or below.

The imprint apparatus 1 includes a mold chuck 10 that holds a mold M, a head 20 that holds and moves the mold chuck 10, a substrate chuck 30 that holds a substrate W, and a substrate stage 40 that holds and moves the substrate chuck 30. The imprint apparatus 1 also includes a shape correcting unit 50 that corrects a shape of a pattern region P of the mold M (a region where a concave-convex pattern is formed), an imaging unit 70, and a control unit 80.

The mold chuck 10 functions as a mold holding unit that absorbs the mold M to hold it. The substrate chuck 30 functions as a substrate holding unit that adsorbs the substrate W to hold it. The substrate stage 40 moves the substrate chuck 30 in an X axis and a Y axis directions to position the substrate W, and changes a portion (shot region) of the substrate W facing the mold M held by the mold chuck 10.

The shape correction unit 50 deforms the pattern region P of the mold M according to a base of the substrate W (a pattern formed on the substrate W).

The imaging unit 70 is configured (disposed) to include the pattern region P of the mold M held by the mold chuck 10 in a field of view. The imaging unit 70 captures at least either one of the mold M and the substrate W to acquire an image. The imaging unit 70 is a camera (spread camera) that observes a contact state between the mold M and the imprint material on the substrate W in imprint processing.

A measurement unit 75 has a function of measuring at least either one of suction pressure of the mold M by the mold chuck 10 and suction pressure of the substrate W by the substrate chuck 30. The measurement unit 75 includes a first measurement unit 75M and a second measurement unit 75W. The first measurement unit 75M measures the suction pressure of the mold M by detecting pressure in a gas exhaust pipe provided on the mold chuck 10 to adsorb the mold M. The second measurement unit 75W measures the suction pressure of the substrate W by detecting pressure in a gas exhaust pipe provided on the substrate chuck 30 to adsorb the substrate W.

In curing processing of the imprint processing, a light emission unit 90 (curing unit) irradiates the mold M with light having a predetermined wavelength, mainly ultraviolet rays having a short wavelength. The light emission unit 90 includes a light source and an optical element that corrects the ultraviolet rays emitted from the light source, to a direction and a position suitable for the imprint material applied onto the substrate W. When adopting a heat-curing method, it is necessary to provide a heat source unit for curing a heat curing mold resin instead of the light emission unit 90.

The control unit 80 includes a central processing unit (CPU) and a memory, and controls each unit of the imprint apparatus 1 to perform the imprint processing. The imprint processing includes supply processing (supply operation), contact processing (contact operation), curing processing (curing operation), and mold release processing (releasing operation). The supply processing supplies the imprint material onto the substrate W. The contact processing brings the mold M into contact with the imprint material on the substrate W. The pattern region P of the mold M (a concave portion of the pattern) is filled with the imprint material when the mold M is brought into contact with the imprint material on the substrate, i.e., when the mold M is pressed onto the imprint material. The curing processing cures the imprint material in a state where the mold M is in contact with the imprint material on the substrate. The mold release processing detaches the mold M from the cured imprint material on the substrate.

The imprint material supply processing can be performed in the imprint apparatus including a coater, a liquid discharge head, and other application units (not illustrated). However, the imprint material can be applied onto the substrate outside the imprint apparatus. In this case, the substrate with the imprint material applied thereto is carried in and then subjected to the imprint processing such as the contact processing, the curing processing, and the mold release processing.

Further, the imprint material curing processing will be described below based on an example where a curing unit such as the light emission unit 90 is provided in the imprint apparatus. However, the curing processing can be performed outside the imprint apparatus.

The imprint apparatus 1 includes a sensor that detects positions of the mold chuck 10 and the substrate chuck 30 to acquire positional information. Further, the imprint apparatus 1 has preset design standard positions of the mold chuck 10 (mold M) and the substrate chuck 30 (substrate W) to be used when the mold M comes into contact with the imprint material on the substrate W. Thus, the control unit 80 can detect, for example, whether the contact processing is in progress, the mold release processing is in progress, or the mold release processing has been performed, based on a difference between the positional information acquired by the sensor and the design standard positions. In this case, the imprint apparatus 1 performs the contact processing and the mold release processing by moving the mold chuck 10 in a Z-axis direction using the head 20 (i.e., by driving the mold chuck 10 as a driving unit). Accordingly, in a case where the positional information for the mold chuck 10 is away from the design standard position, the imprint apparatus 1 detects that the mold release processing is in progress. In a case where the positional information for the mold chuck 10 coincides with the design standard position, the imprint apparatus 1 detects that the contact processing is in progress.

The contact processing and the mold release processing can be implemented by moving the mold chuck 10 in the Z-axis direction as described above, and these pieces of processing can be implemented by moving the substrate stage 40 in the Z-axis direction. Alternatively, a relative distance between the mold M and the substrate W can be adjusted by relatively moving both the substrate stage 40 and the mold chuck 10.

The control unit 80 can detect whether a dechuck of the mold M has occurred on the mold chuck 10 based on whether a suction pressure failure occurred in the first measurement unit 75M. Likewise, the control unit 80 can also detect whether a dechuck of the substrate W has occurred on the substrate chuck 30 based on whether a suction pressure failure occurred in the second measurement unit 75W.

The present disclosure is also applicable to a flattening apparatus that provides a flattening layer using a cured object made of a curable composite on the substrate by curing the imprint material in a state where a material with no pattern (flattening member) is in contact with the curable composite. In this case, a severe accuracy is not required since such pattern transfer as in the imprint apparatus is not performed. Therefore, it is desirable, from a viewpoint of productivity, to perform flattening processing using a flattening member that can collectively flatten the entire substrate surface.

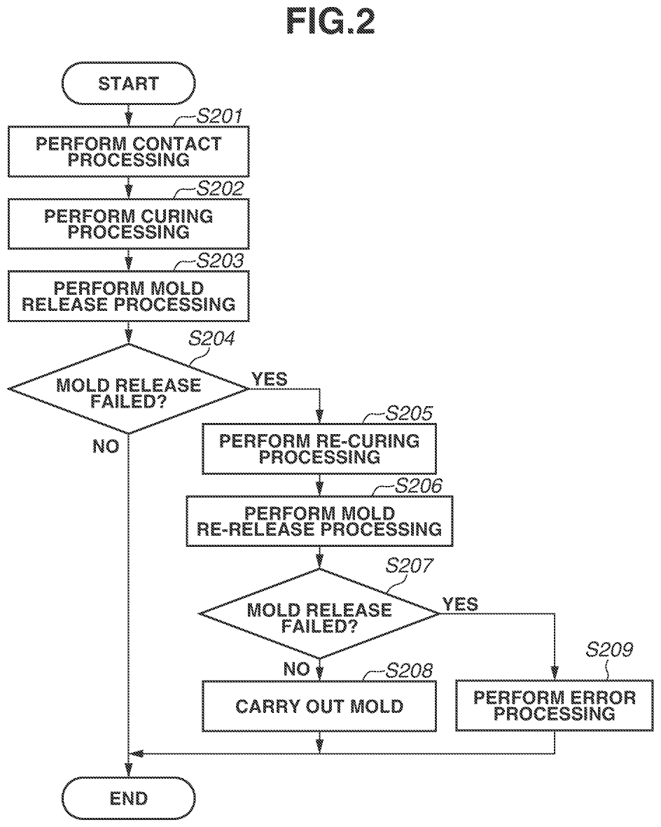

Recovery processing to be performed if the mold release processing failed will be described below. FIG. 2 is a flowchart illustrating the imprint processing including the recovery processing according to a first exemplary embodiment. The processing illustrated in the flowchart in FIG. 2 is implemented by the control unit 80 totally controlling each unit of the imprint apparatus 1. This flowchart will be described below on the premise that the curable composite has been applied onto the substrate W in advance.

In step S201, the control unit 80 controls the mold chuck 10 to bring the pattern region P of the mold M into contact with the substrate W via the imprint material on the substrate W, i.e., to perform the contact processing.

In step S202, the control unit 80 controls the light emission unit 90 to irradiate the imprint material with curing light via the mold M, i.e., to perform the curing processing. More specifically, the imprint material can be cured using light having a 365 nm main wavelength. It is desirable that an emission amount (exposure amount) in this case enables forming a desired pattern structure.

In step S203, to release the mold M from the cured imprint material, the control unit 80 controls the mold chuck 10 to increase the relative distance between the substrate W and the mold M, i.e., to perform the mold release processing.

In step S204, the control unit 80 determines whether the mold release processing in step S203 failed. More specifically, in a case where a suction pressure failure occurs in the first measurement unit 75M or in the second measurement unit 75W, the control unit 80 determines that a dechuck has occurred and thus determines that the mold release processing failed. Even if a dechuck has not occurred, the control unit 80 monitors a mold release force. In a case where a mold release time is longer than a predetermined time or in a case where the mold release force exceeding a setting value is applied, the control unit 80 determines that the mold release processing failed. In a case where the control unit 80 determines that a dechuck has occurred, the control unit 80 controls the mold chuck 10 to perform re-holding processing for the substrate W or the mold M that entered a dechuck state in this step.

In a case where the control unit 80 determines that the mold release processing is normally completed (the mold release processing did not fail) (NO in step S204), the processing ends this flowchart. Then, the processing proceeds to the imprint operation for the next shot region or the substrate. On the other hand, in a case where the control unit 80 determines that the mold release processing failed (YES in step S204), the processing proceeds to steps S205 and S206 (recovery processing).

In step S205, the control unit 80 determines that the normal mold release processing cannot be performed, and performs re-curing processing (additional curing processing) to reduce the mold release force required for releasing the mold M. More specifically, the control unit 80 controls the light emission unit 90 to irradiate the imprint material with curing light via the mold M to reduce the mold release force, i.e., to perform the re-curing processing.

When a curable resin material such as an imprint material is irradiated by predetermined light (mainly light having a short wavelength), molecular chemical bonds can be dissociated. In particular, in macromolecules with polymerized polymerizable monomers, the energy of light having a wavelength of 400 nm or less becomes larger than the dissociation energy of various kinds of chemical bonds. It is desirable to use light having a wavelength of 400 nm or less for the dissociation of the chemical bonds of macromolecules with polymerized polymerizable monomers.

Dissociating the molecular chemical bonds of the curable composite decreases the material strength due to the molecular chemical bonds. With the decrease in the material strength, the mold release force necessary to detach the mold M from the substrate W sandwiching the curable composite decreases, thereby making it easier to release the mold M.

According to the present exemplary embodiment, the wavelength of the light emitted from the light emission unit 90 is light having a main wavelength of 365 nm as described above, so that it can be said that the light contains a wavelength suitable for the dissociation of the macromolecular chemical bonds. Thus, according to the present exemplary embodiment, a common light source can be used for the curing processing and the re-curing processing. Using a common light source in this way enables preventing the increase in complexity and size of the apparatus.

A polymerization reaction occurring in the curing of the curable composite is known to occur in a chain reaction in a short time. On the other hand, the dissociation of a covalent bonding occurs when a covalent bonding portion is irradiated with a light quantity that is equal to or higher than the dissociation energy. The dissociation of the covalent bonding takes a longer time than the polymerization reaction. Therefore, it is desirable that the exposure time in the re-curing processing is longer than (for example, at least 10 times) that in the curing processing.

Different light sources can be used for the curing processing and the re-curing processing. In this case, it is desirable that the light source to be used for the re-curing processing contains light having a shorter wavelength than that of the light source to be used for the regular curing processing. For example, a light source containing light having a main wavelength of 365 nm is used for the curing processing, and a light source containing light having a wavelength of 320 nm or less is used for the re-curing processing. The energy of light having the wavelength of 320 nm or less is larger than the dissociation energy of the chemical bonds of various organic compounds. Using light having such a wavelength enables promoting the dissociation of the chemical bonds of the organic compounds, thereby reducing the mold release force in a more effective way.

Further, it is desirable that an illuminated region in the re-curing processing is larger than that in the curing processing in step S202. By irradiating a sufficient region with the curing light in the re-curing processing, the mold can be released with the reduced mold release force even if the mold release force increases as the curable composite is cured outside an imprint region. Such a phenomenon may possibly occur in a case where the imprint material is applied onto the entire surface of the substrate outside the imprint apparatus 1 or in a case where an imprint material application failure occurs.

In a case where the heat-curing method is employed instead of the photo-curing method, the curable composite is heated and cured using a heat source unit as the curing processing and the additional curing processing. In this case, the curable composite is heated until a state where the dissociation of the chemical bonds can be promoted is obtained, as the additional curing processing.

In step S206, to release the mold M from the cured imprint material, the control unit 80 controls the mold chuck 10 to increase the relative distance between the substrate W and the mold M to perform the mold release processing again (mold re-releasing processing).

In step S207, like in step S204, the control unit 80 determines whether the mold release processing in step S206 failed. The specific determination method is similar to that in step S204, and redundant descriptions thereof will be omitted.

Even if the mold release is successful in the mold re-release processing in step S206, the imprint material having undergone the re-curing processing in step S205 has been degraded because of the dissociation of covalent bonding as described above. Thus, the imprint material is highly likely to be unusable as a desired pattern. Therefore, it is desirable that the pattern of the region having undergone the re-curing processing is not used in the subsequent processing.

In a case where the control unit 80 determines that the mold re-release processing is normally completed (the mold re-release processing did not fail) (NO in step S207), the processing proceeds to step S208. On the other hand, in a case where the control unit 80 determines that the mold re-release processing failed (YES in step S207), the processing proceeds to step S209. In step S209, the control unit 80 performs error processing. In a case where the control unit 80 determines that the mold re-release processing failed, the control unit 80 can repeat steps S205 and S206 several times and then perform the error processing. Specific examples of the error processing include notifying the user that the mold release could not be performed even after performing the mold re-release processing.

In step S208, the control unit 80 carries the mold M out of the apparatus assuming that the mold M has undergone the re-curing processing. Then, the processing exits the flowchart. The mold M carried out in step S208 is cleaned and recovered by a cleaning apparatus outside the imprint apparatus 1.

When the light quantity exceeding the exposure amount most suitable for pattern formation is emitted through the re-curing processing, the chemical bonds are dissociated as described above and the mold release force decreases. Although the mold M can be released from the substrate W, the pattern itself is highly likely to be subjected to a transfer failure.

In other words, it is highly likely that a part of the imprint material remains in the concave pattern of the mold M. Accordingly, if the next imprint processing can be performed with the mold M as it is, the possibility that pattern transfer cannot be normally performed (a transfer failure occurs) is high. Therefore, it is necessary to clean the mold M for recovery and then reuse the mold M.

In a case where a mold cleaning unit (not illustrated) is provided in the imprint apparatus 1, the control unit 80 can clean the mold M by the mold cleaning unit for recovery instead of carrying the mold M out of the apparatus in step S208, and then end the processing. More specifically, after the re-curing processing, the control unit 80 performs control to carry the mold M out of the imprint apparatus 1 or clean the mold M to recover the mold M. By preventing the mold M having undergone a mold release failure from being used for the next imprint processing as it is, the occurrence of a transfer failure can be prevented in the imprint processing.

As described above, in a case where the mold M cannot be released from the substrate W, the present exemplary embodiment subjects the curable composite to the additional curing processing to make it easier to release the curable composite, and then performs the mold release processing again. This enables releasing the mold M even without performing the recovery processing by an operator, thereby making it possible to provide a molding apparatus that is beneficial in productivity.

Recovery processing to be performed in a case where the mold release processing failed according to a second exemplary embodiment will be described below. The first exemplary embodiment has been described above based on an example where the mold release processing is performed upon completion of the re-curing processing. According to the present exemplary embodiment, however, the re-curing processing and the mold release processing are performed at the same time. The present exemplary embodiment will be described below centering on portions different from the first exemplary embodiment, and similar descriptions will be omitted.

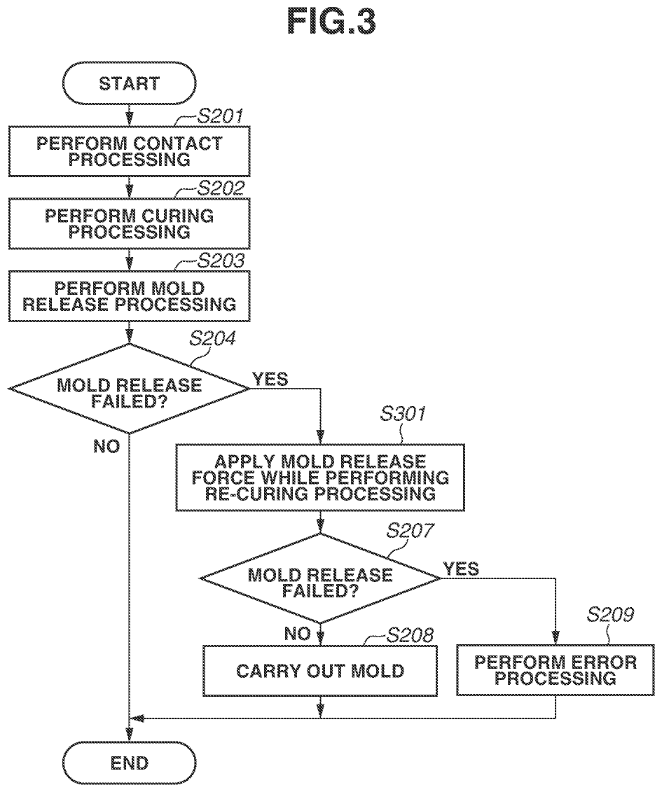

FIG. 3 is a flowchart illustrating imprint processing including the recovery processing according to the present exemplary embodiment. Processing illustrated in the flowchart in FIG. 3 is implemented when the control unit 80 totally controls each unit of the imprint apparatus 1. The flowchart will be described below on the premise that the curable composite has been applied onto the substrate W in advance. Steps S201 to S204 and S207 to S209 in FIG. 3 are similar to those in the processing in FIG. 2, and redundant descriptions will be omitted.

In step S301, to reduce the mold release force required when releasing the mold M since the normal mold release processing is not possible, the control unit 80 controls the mold chuck 10 to increase the relative distance between the substrate W and the mold M (mold re-release processing) while performing the re-curing processing.

Possible causes of the mold release failure in the mold release processing in step S203 include three different factors. The first factor is whether an unforeseen mold release force is required. The second factor is the required mold release force. And, the third factor is intensity of the predetermined light and the time period during which the light is emitted. In this case, by keeping applying such a mold release force that does not cause a dechuck while emitting light for the re-curing processing in step S301, the mold M can be released through minimum re-curing processing. Performing such mold re-release processing enables preventing the irradiation time for reducing the mold release force from being unnecessarily prolonged, thus shortening an idle time of the imprint apparatus and preventing the productivity degradation.

As described above, in a case where the mold M cannot be released from the substrate W, the present exemplary embodiment also subjects the curable composite to the additional curing processing to make it easier to release the curable composite and then performs the mold release processing again. This enables releasing the mold M even without performing the recovery processing by the operator, thereby making it possible to provide a molding apparatus that is beneficial in productivity.

### About Product Manufacturing

A cured material pattern formed using the above-described imprint apparatus 1 is permanently used for at least a part of various products or temporarily used in manufacturing various products.

Examples of the products include an electrical circuit element, an optical element, micro electro mechanical systems (MEMS), a recording element, a sensor, and a mold. Examples of the electrical circuit element include a volatile or a nonvolatile semiconductor memory such as a dynamic random access memory (DRAM), a static random access memory (SRAM), a flash memory, and a magnetoresistive random access memory (MRAM), and a semiconductor device such as a large scale integrated circuit (LSI), a charge coupled device (CCD) sensor, an image sensor, and a field-programmable gate array (FPGA). Examples of the mold include a mold for imprint.

A cured material pattern is used as it is or temporarily used as a resist mask, as at least a part of component members of the above-described products. A resist mask is removed after completion of etching or ion implantation in substrate processing step.

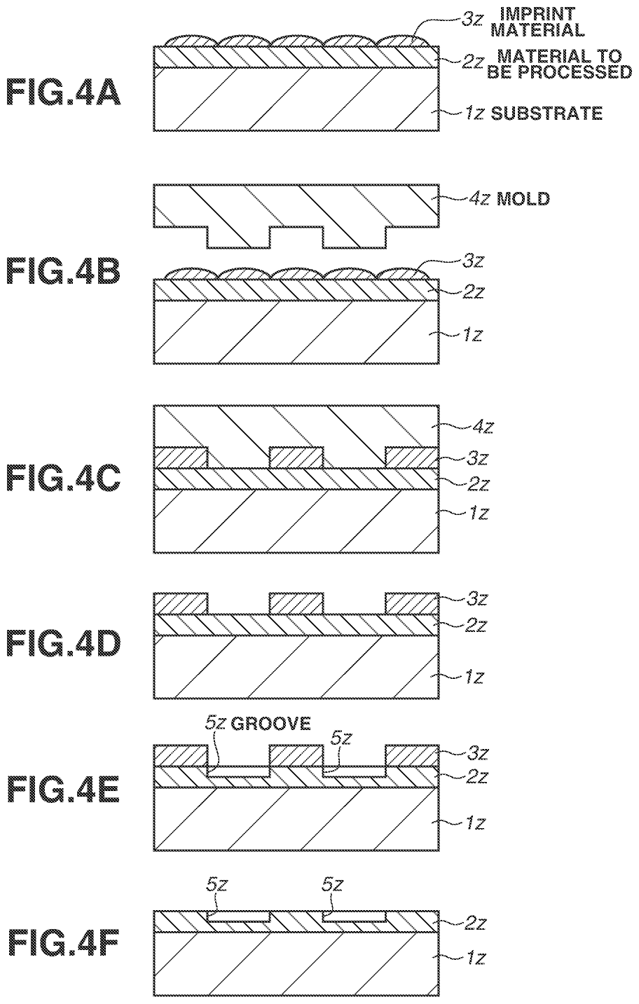

The following describes a product manufacturing method for forming a pattern on a substrate using the imprint apparatus 1, processing the substrate with the pattern formed thereon, and manufacturing a product from the substrate processed in this way. As illustrated in FIG. 4A, a substrate 1z such as a silicon wafer is prepared. A material to be processed 2z such as an insulator is formed on the surface of the substrate 1z. Then, an imprint material 3z is applied onto the surface of the material to be processed 2z using an ink-jet method or the like. FIG. 4A illustrates a state where the imprint material 3z having a shape of a plurality of droplets is applied onto the substrate 1z.

As illustrated in FIG. 4B, a mold 4z for imprint is disposed to face the imprint material 3z on the substrate 1z. The surface of the mold 4z with a concave-convex pattern formed thereon is oriented toward the imprint material 3z. As illustrated in FIG. 4C, the substrate 1z with the imprint material 3z applied thereto and the mold 4z are brought into contact with each other and then pressurized. A gap between the mold 4z and the material to be processed 2z is filled with the imprint material 3z. In this state, when the imprint material 3z is irradiated with light as the curing energy via the mold 4z, the imprint material 3z is cured.

As illustrated in FIG. 4D, after the imprint material 3z has been cured, the mold 4z and the substrate 1z are detached from each other. In a case where such mold release is successful, a pattern of the cured imprint material 3z is formed on the substrate 1z. The pattern of the cured material is shaped so that concave portions of the mold 4z fit convex portions of the cured imprint material 3z, and convex portions of the mold 4z fit concave portions of the cured imprint material 3z. This means that the concave-convex pattern of the mold 4z has been transferred onto the imprint material 3z.

As illustrated in FIG. 4E, when etching is performed using the pattern of the cured imprint material 3z as an etching-proof mask, surface portions of the material to be processed 2z where the cured imprint material 3z is absent or thinly remains are removed to form grooves 5z. As illustrated in FIG. 4F, when the pattern of the cured imprint material 3z is removed, a product having the grooves 5z formed on the surface of the material to be processed 2z can be obtained. Although the pattern of the cured imprint material 3z is removed in this example, the cured imprint material 3z can be used as a film for insulation between layers included in a semiconductor device, more specifically, as a component member of the product, without being removed after the processing.

The product manufacturing method also includes a step of forming a pattern on an imprint material supplied (applied) onto a substrate using the above-described imprint apparatus (imprint method), and a step of processing the substrate with the pattern formed thereon in the above-described step. The manufacturing method further includes other known processes (oxidization, coating, vapor deposition, doping, flattening, etching, resist removing, dicing, bonding, packaging and the like). The product manufacturing method according to the present exemplary embodiment can be said to be beneficial in at least one of performance, quality, productivity, and production cost of products in comparison with the conventional method.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2021-099402, filed Jun. 15, 2021, which is hereby incorporated by reference herein in its

What is claimed is:

1. A molding apparatus comprising:
a mold holding unit configured to hold a mold;
a substrate holding unit configured to hold a substrate;
a driving unit configured to adjust a relative distance between the mold held by the mold holding unit and the substrate held by the substrate holding unit; and
a control unit configured to control the driving unit to perform curing processing for curing a curable composite in a state where the mold held by the mold holding unit and the substrate held by the substrate holding unit are in contact with each other through the curable composite, and to perform mold release processing of the mold from the substrate after the curing processing,
wherein, when the mold release processing fails, the control unit performs control to performing additional processing on the curable composite between the mold held by the mold holding unit and the substrate held by the substrate holding unit.

2. The molding apparatus according to claim 1,
wherein the curable composite is a photo-curable resin,
wherein the curing processing is performed by emission of light for curing the photo-curable resin from a light emission unit, and
wherein the additional curing processing is also performed using the light emission unit.

3. The molding apparatus according to claim 1,
wherein the curable composite is a photo-curable resin,
wherein the curing processing is performed by emission of light for curing the photo-curable resin from a light emission unit, and
wherein the additional curing processing is performed by the emission of light having a shorter wavelength than the light emitted by the light emission unit.

4. The molding apparatus according to claim 1, wherein, upon completion of the additional curing processing, the control unit controls the driving unit to perform the mold release processing again.

5. The molding apparatus according to claim 1, wherein the control unit controls the driving unit to perform the mold release processing together with the additional curing processing.

6. The molding apparatus according to claim 1,
wherein the mold has a concave-convex pattern, and
wherein the molding apparatus is an imprint apparatus configured to mold a concave-convex pattern of the curable composite on the substrate using the concave-convex pattern of the mold.

7. The molding apparatus according to claim 1, wherein, upon completion of the additional curing processing, the control unit performs control to carry the mold out of the molding apparatus or clean the mold.

8. A molding method comprising:
performing first curing processing for curing a curable composite in a state where a mold held by a mold holding unit and a substrate held by a substrate holding unit are in contact with each other through the curable composite;
performing, upon completion of the first curing processing, mold release processing of the mold from the substrate; and
performing, in a case where the mold release processing fails, additional second curing processing on the curable composite between the mold held by the mold holding unit and the substrate held by the substrate holding unit.

9. A product manufacturing method comprising:
processing the substrate using the molding apparatus according to claim 1; and
manufacturing a product by processing the processed substrate.
